(19) United States
(12) Patent Application Publication
(10) Pub. No.: US 2005/0194662 A1
(43) Pub. Date: Sep. 8, 2005

(54) Semiconductor component and micromechanical structure

(75) Inventors: Gerhard Schmidt, Wernberg-Wudmath (AT); Rudolf Zelsacher, Klagenfurt (AT); Michael Bar, Mallnitz (AT); Wolfgang Werner, Munchen (DE); Bernhard Winkler, Munchen (DE)

Correspondence Address: Maginot, Moore & Beck;Bank One Tower, Suite 3000, 111 Monument Circle, Indianapolis, IN, 46204, US

(73) Assignee: Infineon Technologies AG, Munchen (DE)

(21) Appl. No.: 11/039,068

(22) Filed: Jan. 20, 2005

(30) Foreign Application Priority Data
Jan. 20, 2004 (DE) 10 2004 002 908.3

(51) Int. Cl. H01L 23/58

(52) U.S. Cl. 257/646

(57) ABSTRACT

A semiconductor component (1) includes a substrate, an active area (2), formed in/on the substrate, and a passivation layer (5) which is provided at least above part of the active area (2). The passivation layer (5) at least partially comprises amorphous, hydrogen-doped carbon. The provision of a passivation layer of this type allows the semiconductor component (1) to be effectively protected against environmental influences.

The invention relates to a semiconductor component and to a micromechanical structure.

Above the electrically active areas, semiconductor components generally have a passivation layer, which may comprise a plurality of sublayers. The passivation layer serves primarily to ensure the long-term reliability of the semiconductor components. For example, the passivation layer protects the semiconductor component from the penetration of moisture or ionic impurities. Penetration of moisture into the edge region of the chip, for example, would lead to a drop in the blocking ability of the semiconductor component. Alkali metal contaminations, on the other hand (for example Na⁺ and K⁺), can lead to a drift in the threshold voltage in MOS components on account of their high mobility in the gate oxide.

The passivation layer should be designed in such a way that it can withstand the peak field strengths at the surface of the semiconductor component. Depending on the design of the semiconductor component, peak field strengths of this type may far exceed the bulk breakdown field strength (approx. 200 kV/cm in the case of silicon).

The passivation layer usually consists of Si₃N₄. This material is distinguished by the fact that it effectively prevents the penetration of moisture and alkali metal contaminations. To ensure good bonding of the Si₃N₄ passivation layer to the semiconductor component, first of all an interlayer (for example SiO₂) is generally applied to the semiconductor component and then the passivation layer is deposited on the interlayer.

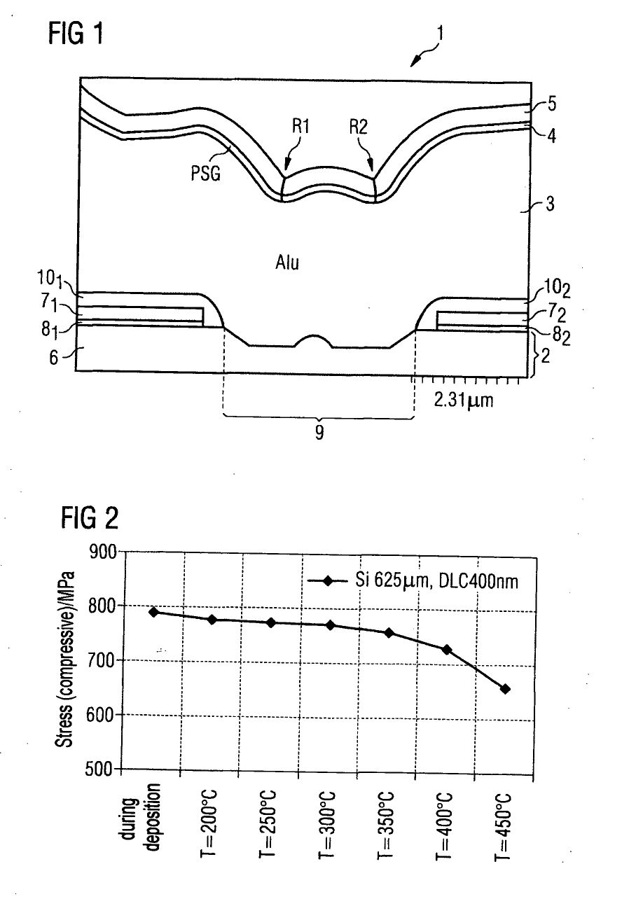

FIG. 1 shows the typical layer structure of a semiconductor component with passivation layer: a cell of an MOS power transistor 1 has an active area 2, a metallization layer 3 (preferably of aluminum) provided above the active area 2, an interlayer 4 (preferably of phosphorus-doped oxide) applied to the metallization layer 3, and a passivation layer 5 of Si₃N₄. The excerpt of the active area 2 shown in FIG. 1 reveals a semiconductor layer 6 which has p- and/or n-doped regions (not specifically shown in FIG. 1). A first and a second gate 7₁, 7₂, which are electrically insulated from the active area 2 by a first and a second gate oxide layer 8₁, 8₂ are provided between the active area 2 and the metallization layer 3. The upper region of the first and second gates 7₁, 7₂ is covered by a first and second insulation layer 10₁, 10₂, for example BPSG (borophosphosilicate glass). The metallization layer 3 is used for contact-connection of the semiconductor layer 6, the contact-connection being effected via a contact hole 9.

The interlayer 4 and the passivation layer 5 are usually deposited by means of a PECVD process (Plasma Enhanced Chemical Vapor Deposition) by radiofrequency excitation of a precursor. The process temperature is selected in such a way that corresponding influences on the metallization layer 3 are minimized.

Since the surface structure of the active area 2 is not planar, but rather has steps or sharp edges in particular in the region of the contact hole 9, the passivation layer 5 likewise has certain “steps” above the contact hole 9. However, these “steps” can easily lead to the formation of cracks within the passivation layer 5, which are denoted by reference symbols R1, R2 in FIG. 1.

These cracks originate, inter alia, from a relatively high mechanical stress in passivation layers which are deposited by means of a PECVD process. The mechanical stress typically has values of up to 200 MPa of compressive stress and/or 500 MPa of tensile stress. In particular tensile stress is critical, since it can very easily lead to the passivation layer flaking off. To allow passivation layers which are stable in the long term to be produced, therefore, it is desirable to limit or reduce stress levels. Mechanical stress can be reduced by suitably setting the process parameters used for the PECVD process for depositing the passivation layer.

However, even optimized process parameters cannot avoid cracks in the passivation layers, and moisture and/or alkali metal contaminations enter the semiconductor component. Consequently, despite the application of a passivation layer, the long-term reliability of the semiconductor component cannot be ensured to a sufficient extent. Furthermore, the problem arises of the high passivation stress leading to the formation of voids in the metallization layer 3, which can only be partially compensated for by the interlayer 4.

Passivation layers also play an important role in the field of micromechanics. To protect the micromechanical structure from environmental influences, the surface of this structure is generally at least partially coated with a passivation layer. The passivation layer offers protection, for example, against mechanical loads, chemical corrosion and against moisture.

Since the influence of the passivation layer on the mechanical properties of the micromechanical structure is to be minimized, it is advantageous to keep corresponding passivation layers as thin as possible (typically below 100 nm).

As has already been mentioned, it is known from semiconductor technology to use passivation layers made from silicon nitride with a thickness of several hundred nm. Passivation layers of this type can only be used to a very limited extent in combination with micromechanical structures: for example, the mechanical properties, which depend on the process used to produce the passivation layers, are not sufficiently stable in the long term under high thermal loads. Furthermore, on account of the high layer thickness of the passivation layer, the mechanical influence of this layer on the micromechanical structure is considerable. If the layer thicknesses are reduced (layer thickness less than 100 nm), in order to reduce the mechanical influence, there is once again a risk of holes being present in the passivation layer and therefore of the sealing function which it provides with respect to moisture/contamination being lost.

As an alternative to silicon nitride, it is also known to use titanium nitride to passivate micromechanical structures. However, this material has the drawback that on account of the (partially) metallic properties, only inadequate electrical insulation can be achieved. Furthermore, in the event of excessive mechanical loads, plastic deformation is produced in the passivation layer, which in turn leads to a drift in the micromechanical structure.

The object on which the invention is based is that of providing a semiconductor component and/or a micromechanical structure in which the abovementioned problems are avoided.

To achieve the object, the invention provides a semiconductor component in accordance with patent claim 1. Furthermore, the invention provides a micromechanical structure as described in patent claim 9. Advantageous embodiments and refinements of the concept of the invention are given in respective subclaims.

The semiconductor component according to the invention includes a substrate, an active area which is formed in/on the substrate, and a passivation layer which is provided at least above part of the active area. One significant aspect of the invention is that the passivation layer at least partially comprises amorphous, hydrogen-doped carbon.

The passivation layer preferably covers the entire active area. The passivation layer is usually also provided above the edge region of the semiconductor component, so that it covers the entire surface of the semiconductor component.

In this context, the term “active area” is to be understood as meaning that part of the substrate and/or the semiconductor regions formed therein/thereon in which (while the semiconductor component is operating) charge carriers can move. Therefore, the term “active area” encompasses in particular source, body, drift or drain regions; in a broader sense, insulation layers which have been applied to the semiconductor layers and/or conductor layers acting as a gate can also be interpreted as parts of the active area.

The use of amorphous, hydrogen-doped carbon as passivation material has the advantages of offering good resistance to the penetration of moisture and foreign ions and also a high electrical robustness. Furthermore, a passivation material of this type has a mechanical stress which is relatively low compared to Si₃N₄ layers, with the result that the risk of cracks forming within the passivation layer can be reduced in particular at steps/sharp edges. Under suitable deposition conditions, carbon layers of this type have diamond-like properties and consequently they have also been referred to as “DLC” (diamond-like carbon).

According to the literature (2), amorphous, hydrogen-containing carbon layers have compressive stress levels which are of the same order of magnitude as for Si₃N₄ layers, stress levels within a range from 500 MPa to 7 GPa being expected. A discovery which has been made in connection with the invention is that the actual compressive stress levels for amorphous, hydrogen-containing carbon layers are far lower than those given in the literature. This discovery is based on measurement results which have been obtained on the basis of a comparison of wafer bow before and after the deposition. A contactless wafer geometry measuring appliance MX203 produced by Eichhorn und Hausmann, Karlsruhe, was used for this purpose. The measurements revealed a compressive stress level of the order of magnitude of approximately 5000 MPa for a 120 nm thick Si₃N₄ layer and a wafer thickness of 630 μm, whereas a compressive stress of approximately 800 MPa was determined for a 400 nm thick carbon layer according to the invention.

The thickness of the passivation layer of a semiconductor component according to the invention should be in a range from 20 nm to 1 μm. In a particularly preferred embodiment, the thickness of the passivation layer is approximately 300 nm. However, the invention is not restricted to these values.

The passivation layer may on the one hand be applied direct to a metallization layer which has been applied for contact-connection of the active area. However, it is preferable for an interlayer, consisting, for example, of phosphorus-doped oxide, to be provided between the passivation layer and the metallization layer. This interlayer can be dispensed with if good adhesion of the passivation layer to the metallization layer (preferably aluminum) and a sufficiently low stress level of the passivation layer have been ensured by suitable setting of the PECVD process parameters.

The passivation layer can be heat-treated at a temperature above 400° C., which reduces the compressive stress. It is preferable for the heat treatment to be carried out over a period of 30 minutes. Furthermore, the temperatures during the heat treatment should not be above 500° C., since otherwise hydrogen diffuses out of the carbon layers, which causes a change in the structural properties of the semiconductor component.

If a deposition process is used to produce the passivation layer, good bonding of the passivation layers to silicon or SiO₂ can be ensured by the formation of SiC bonds at suitable interfaces. Furthermore, since the passivation layers used in accordance with the invention are chemically inert and impermeable with respect to liquids, they are eminently suitable as a diffusion barrier (literature (2)). The PECVD process therefore allows the production of pinhole-free, high-density layers which are amorphous under X-ray analysis. Furthermore, good edge coverage of semiconductor topology is made possible.

A parallel plate reactor, in which radiofrequency power is capacitively introduced into a plasma is usually used to carry out the PECVD process. The process gas used in this case is gaseous hydrocarbons. Standard frequencies are 13.56 MHz, but other frequencies, for example in the 100 kHz range, are also possible.

As an alternative to the PECVD process, it is also possible to use processes which are based on inductive introduction of the radiofrequency power, on a direct current glow discharge at a sufficiently high DC voltage (300-2000 V), a direct current glow discharge using a hot filament at low voltage (50 V), or on a pulsed discharge and magnetic acceleration of ions. Still further processes use a solid carbon source (graphite), with (optional) addition of hydrogen during the deposition. Examples of these include argon sputtering, laser evaporation and deposition by means of an arc.

To ensure electrical neutrality and to avoid parasitic leakage currents, the resistivity of the DLC layer should be ρ≧10⁸ Ω cm.

According to the invention, therefore, a barrier in the form of a DLC layer on a contact hole or via metallization with the corresponding topology is used, since if Si₃N₄ is used, it is not possible to ensure sufficient flank protection. Furthermore, it is possible for the DLC layers to be deposited as a barrier on electrically active passivation layers (such as amorphous silicon or polysilicon).

The invention can be applied to any desired semiconductor components, in particular to transistors, diodes, IGBTs, MOS structures, Cool-MOS structures, etc., and to semiconductor components which form a combination of these components.

Furthermore, the invention provides a micromechanical structure, the surface or surface structure of which is at least partially covered with a passivation layer in order to protect the micromechanical structure from environmental influences. The passivation layer at least partially comprises amorphous, hydrogen-doped carbon.

The thickness of the passivation layer is preferably in a range between 50 and 100 nm, in order to minimize the mechanical influence of the passivation layer on the micromechanical structure. Despite this low layer thickness, it is possible to trim all the other desired layer properties, such as layer stress, hardness, density, chemical resistance, long-term stability with respect to moisture and electrical insulation, to values which are required or desirable for micromechanical structures.

With regard to the process used for the passivation layer., the statements which have been made in connection with semiconductor components apply analogously. By way of example, it is possible to reduce the mechanical stress after deposition of the DLC layer by carrying out a heat treatment process at above 400° C.

Therefore, aC:h (amorphous hydrogenized carbon) can be used as passivation material in order to protect against environmental influences in microelectronics and micromechanics. The layer properties such as hardness, layer stress, layer thickness, electrical conductivity, can be set in a wide range during the production process and matched to the particular application. In long-term load tests, it has been possible to demonstrate that aC:h layers with a thickness of from 50 to 100 nm can be produced with a stability which is similar to or even higher than that of silicon nitride or titanium nitride when subjected to moisture loads. An aC:h passivation layer is therefore eminently suitable as a moisture barrier for micromechanical structures. On account of the high density, aC:h is likewise an effective barrier against ions and offers protection against damage to electrical components through ion diffusion. The high hardness which can be achieved for aC:h layers, even up to diamond-like properties offers good protection against mechanical damage, such as scratches on the chip surface.

The layer stress of the passivation layer on mechanically movable structures has a considerable influence on the susceptibility to cracking or the formation of cracks in the structure. Tests carried out using different passivation layers have established that, for example in the case of pressure sensor membranes, the susceptibility to cracking is determined to a decisive degree by the mechanical properties of the passivation layer on the membrane. In the case of layers with a low layer stress, the susceptibility to cracking is considerably reduced compared to layers with a high layer stress, or cracks can be avoided even under strong mechanical loads e.g. a sawing process. The advantage of aC:h as a passivation material compared to the materials which have been used hitherto is that different positive layer properties, such as layer stress, hardness, density, chemical resistance, long-term stability with respect to moisture loads and electrical insulation, can be combined by suitable selection of the production process. The properties and advantages listed for aC:h as passivation material are likewise crucial for other applications, such as, for example acceleration sensors or rotation rate sensors, with in some cases very complex mechanically movable structures.

The invention can be applied to any desired micromechanical structures, for example to acceleration sensors, pressure sensors, rotation rate sensors, piezoelectric elements or the like.

The invention is explained in more detail below with reference to the figures in the form of an exemplary embodiment.

In the drawing:

FIG. 1 shows a cross-sectional illustration of an excerpt from a planar MOS power transistor with passivation layer in accordance with the prior art;

FIG. 2 shows a diagram revealing the relationship between compressive stress of a passivation layer according to the invention and a heat treatment (conditioning process) of the passivation layer;

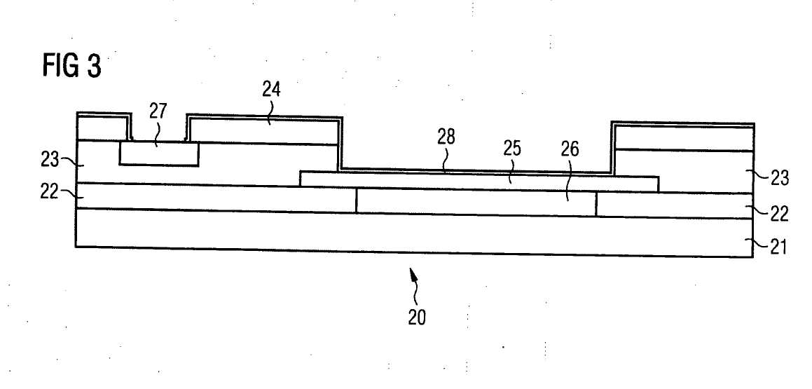

FIG. 3 shows a preferred embodiment of a micromechanical structure according to the invention.

Throughout the figures, identical or corresponding parts are denoted by the same reference symbols.

The MOS transistor shown in FIG. 1 has already been dealt with in the introduction to the description; therefore, this figure is not explained again here. An MOS transistor according to the invention differs from the transistor shown in FIG. 1 only by virtue of the fact that the material of the passivation layer 5 consists of amorphous, hydrogen-doped carbon instead of silicone nitride. Furthermore, the interlayer 4 can be omitted.

FIG. 2 shows the compressive stress profile within an amorphous, hydrogen-doped carbon layer which is used to passivate a semiconductor component according to the invention. This figure clearly reveals that the stress can be reduced by a heat treatment process. The higher the heat treatment temperature, the greater the extent to which the stress is reduced. The stress levels were in this case determined by measuring the “wafer bow” after various heat treatment steps. The “wafer bow” is to be understood as meaning the convex or concave curvature of a wafer which is caused, for example by the mechanical stress from the applied layer system or by different expansion coefficients. The heat treatment time was 30 minutes.

The following text, with reference to FIG. 3 is to provide a more detailed explanation of an example of a micromechanical structure according to the invention.

An integrated, micromechanically produced capacitive pressure sensor 20 includes a substrate 21, an approx. 0.5 μm thick sacrificial layer 22 applied to it consisting of silicon oxide, for example, an intermetal oxide layer 23 applied to the sacrificial layer 22, and a first passivation layer 24 applied to the intermetal oxide layer 23. Furthermore, the pressure sensor 20 has a membrane layer 25, which has been applied to the sacrificial layer 22 and covers a void 26 formed in the sacrificial layer 22. The membrane layer 25 consists, for example of 0.5 to 1 μm thick polycrystalline silicon. The intermetal oxide layer 23 and the first passivation layer 24 only cover an edge region of the membrane layer 25, so that sufficient mobility of the membrane layer 25 is ensured. Furthermore, a terminal (pad) 27 for electrical contact connection of the pressure sensor 20 is provided within the pressure sensor 20. The terminal 27 has been formed within the intermetal oxide layer 23 with the first passivation layer 24 having been etched away above the terminal 27. The principle of the sensor consists in measuring a capacitance between the substrate 21 and the membrane layer 25, which capacitance is altered as a function of the external pressure and a resultant bending of the membrane layer 25.

According to the invention, a second passivation layer of amorphous, hydrogen-doped carbon 28 is then applied over the surface of the entire pressure sensor 20, this second passivation layer having an opening only above the terminal 27 in order to uncover corresponding bonding contacts. To minimize the mechanical influence of the second passivation layer 28, the thickness of the second passivation layer 28 should be no greater than approximately 100 nm. The second passivation layer 28 allows (as a nitride replacement) the desired protection of the pressure sensor 20 with respect to environmental influences to be achieved in an effective way without the mechanical influence of this layer on the functioning of the pressure sensor 20 being excessive.

Literature:

/1/G. Schumicki, P. Seegebrecht, “Prozesstechnologie” [Process engineering], Springer (1991)

/2/A. Grill, Plasma-deposited diamondlike carbon and related materials, IBM Journal of Research and Development, Vol. 43, 1/2, 1999

1-12. (canceled)

13. A semiconductor component comprising:
a) a substrate;
b) an active area formed in or on the substrate, and
c) a passivation layer provided above at least part of the active area, the passivation layer at least partially comprising amorphous, hydrogen-doped carbon.

14. The semiconductor component of claim 13 wherein the passivation layer is made by a process that includes heating the passivation layer above a temperature of 400° C.

15. The semiconductor component of claim 13 wherein the thickness of the passivation layer is between 20 nm and 1 μm.

16. The semiconductor component of claim 15 wherein the thickness of the passivation layer is approximately 300 nm.

17. The semiconductor component of claim 13 further comprising a metallization layer between the active area and the passivation layer, the metallization layer providing contact-connection of the active area.

18. The semiconductor component of claim 17 wherein a layer of phosphorus-doped oxide is provided between the passivation layer and the metallization layer.

19. The semiconductor component of claim 17 wherein the metallization layer comprises aluminum.

20. The semiconductor component of claim 13 wherein the semiconductor component forms at least one element selected from the group consisting of a transistor, a diode, an IGBT, or a MOS structure.

21. A micromechanical structure comprising
a) a surface; and
b) a passivation layer applied to the surface, wherein the passivation layer comprises amorphous, hydrogen-doped carbon.

22. The micromechanical structure of claim 21 wherein the passivation layer is made by a process that includes heating the passivation layer above a temperature of 400° C.

23. The micromechanical structure of claim 21 wherein the thickness of the passivation layer is between 50 nm and 100 nm.

24. The micromechanical structure of claim 21 wherein the micromechanical structure is selected from the group consisting of an acceleration sensor, a pressure sensor, a rotation rate sensor, or a piezoelectric element.

25. A method of making a semiconductor component, the method comprising:
a) providing a substrate;
b) forming an active area in or on the substrate, and
c) forming a passivation layer above at least a part of the active area, wherein the passivation layer comprises amorphous, hydrogen-doped carbon.

26. The method of claim 25 further comprising the step of heating the passivation layer above a temperature of 400° C.

27. The method of claim 25 wherein the thickness of the passivation layer is between 20 nm and 1 μm.

28. The method of claim 26 further comprising the step of forming a metallization layer between the active area and the passivation layer.

29. A method of protecting a micromechanical structure, the method comprising:
a) providing a micromechanical structure having a surface; and
b) applying a passivation layer to the surface of the micromechanical structure, the passivation layer comprising amorphous, hydrogen-doped carbon.

30. The method of claim 29 further comprising the step of heating the passivation layer above a temperature of 400° C.

31. The method of claim 29 wherein the thickness of the passivation layer is between 50 nm and 100 nm.

32. The method of claim 29 wherein the micromechanical structure is selected from the group consisting of an acceleration sensor, a pressure sensor, a rotation rate sensor, or a piezoelectric element.
